(19) United States
(12) Patent Application Publication
(10) Pub. No.: US 2022/0154070 A1
(43) Pub. Date: May 19, 2022

(54) NITRIDE FLUORESCENT MATERIAL AND LIGHT EMISSION DEVICE

(71) Applicant: DENKA COMPANY LIMITED, Tokyo (JP)

(72) Inventors: Marina TAKAMURA, Tokyo (JP); Tomohiro NOMIYAMA, Tokyo (JP); Yusuke TAKEDA, Tokyo (JP)

(73) Assignee: DENKA COMPANY LIMITED, Tokyo (JP)

(21) Appl. No.: 17/601,870

(22) PCT Filed: Mar. 24, 2020
(86) PCT No.: PCT/JP2020/013142

§ 371 Date: Oct. 6, 2021

(30) Foreign Application Priority Data
Apr. 9, 2019 (JP) 2019-074150

(51) Int. Cl. C09K 11/77; C01B 21/06; H01L 33/50

(52) U.S. Cl. CPC C09K 11/77348; C01P 2002/54; H01L 33/502; C01B 21/0602

(57) ABSTRACT

A nitride fluorescent material represented by General Formula: MAlSiN₃ (M=Ca, Sr) in which a part of M is substituted with Eu and a main crystal phase has the same structure as that of a CaAlSiN₃ crystal phase, in which a light emission peak wavelength is 640 nm or more, and a half width of the light emission peak wavelength is 80 nm or less.

### TECHNICAL FIELD

The present disclosure relates to a nitride fluorescent material and a light emission device.

### BACKGROUND ART

A white light emission diode (a white LED) has been widely used for illuminations. The white LED is a device that includes a light emission element such as a blue light emission diode, and a fluorescent material, and emits white light by color mixture of blue light emitted from the light emission element and fluorescence emitted from the fluorescent material. The generally used white LED lacks red light. Therefore, various red fluorescent materials have been studied in order to reproduce a white color close to natural light and improve color rendering properties.

A nitride fluorescent material such as a CASN fluorescent material and a SCASN fluorescent material has been known as the red fluorescent material (for example, Patent Literature 1 or the like). In general, such nitride fluorescent materials are synthesized by heating a raw material powder containing a europium oxide or a europium nitride, a calcium nitride, a silicon nitride, and an aluminum nitride.

### CITATION LIST

### Patent Literature

Patent Literature 1: International Publication WO 2005/052087

### SUMMARY OF INVENTION

### Technical Problem

A red fluorescent material that has a light emission peak wavelength in a long wavelength range and exhibits sufficient light emission intensity has been required from the viewpoint of obtaining a light emission device excellent in the color rendering properties. In order to obtain such a red fluorescent material, a method of increasing the content of europium that is a light emission center has been considered. However, according to the studies of the present inventors, in the case of increasing a blending amount of a europium oxide or a europium nitride in a raw material powder, in a nitride fluorescent material to be obtained, a light emission peak wavelength is shifted to a long wavelength, but light emission intensity tends to decrease. There is room for improvement from the viewpoint of obtaining a red fluorescent material having a light emission peak wavelength in a long wavelength range and sufficient light emission intensity.

In addition, the fluorescent material used in the light emission device may be exposed to a high temperature by radiation heat due to light emission from the light emission element or the like. In general, in the fluorescent material, the light emission intensity tends to decrease at a high temperature. It is useful when there is a red fluorescent material in which light emission intensity is excellent and a decrease in the light emission intensity is suppressed even at a high temperature.

An object of the present disclosure is to provide a nitride fluorescent material in which light emission intensity is excellent and a decrease in light emission intensity is suppressed even at a high temperature. In addition, another object of the present disclosure is to provide a light emission device in which a decrease in luminance is suppressed even at a high temperature.

### Solution to Problem

One aspect of the present disclosure provides a nitride fluorescent material represented by General Formula: MAlSiN₃ (M=Ca, Sr) in which a part of M is substituted with Eu and a main crystal phase has the same structure as that of a CaAlSiN₃ crystal phase, in which a light emission peak wavelength is 640 nm or more, and a half width of the light emission peak wavelength is 80 nm or less.

Since the nitride fluorescent material described above has the light emission peak wavelength in a red region and a small half width of the light emission peak wavelength, the nitride fluorescent material is excellent in light emission intensity. In the fluorescent material described above, a decrease in the light emission intensity is suppressed even at a high temperature. The reason that in the nitride fluorescent material, the decrease in the light emission intensity is suppressed even at a high temperature is not obvious, but the present inventors have assumed that this is because the occurrence of a defect in a crystalline lattice of the nitride fluorescent material is suppressed, and an energy loss due to the internal defect is mitigated in the peak wavelength range described above.

The nitride fluorescent material described above may further contain halogen as a constituent element. In a case where the nitride fluorescent material contains halogen, the nitride fluorescent material is capable of having the light emission peak wavelength in a longer wavelength range, which is more useful as a red fluorescent material.

In addition, the content of halogen of the nitride fluorescent material described above may be 200 μg/g or more. By setting the content of halogen to be in the range described above, the light emission intensity may be further improved, and a fluorescent material may be obtained in which a decrease in the light emission intensity at a high temperature is further suppressed.

Another aspect of the present disclosure provides a light emission device, including: the nitride fluorescent material described above; and a light emission element.

Since the light emission device described above includes the nitride fluorescent material, and a decrease in light emission intensity at a high temperature is suppressed, a decrease in luminance due to long-term use of the light emission device may be suppressed.

### Advantageous Effects of Invention

According to the present disclosure, it is possible to provide a fluorescent material in which light emission intensity is excellent and a decrease in the light emission intensity is suppressed even at a high temperature. In addition, according to the present disclosure, it is possible to provide a light emission device in which a decrease in luminance is suppressed even at a high temperature.

### BRIEF DESCRIPTION OF DRAWINGS

FIG. 1 is a schematic sectional view illustrating an example of a light emission device.

### DESCRIPTION OF EMBODIMENTS

Hereinafter, embodiments of the present disclosure will be described with reference to the drawings, in some cases. Here, the following embodiments are an example in order to describe the present disclosure, and the present disclosure is not intended to be limited to the following contents. A positional relationship such as the left, right, top, bottom, or the like is based on a positional relationship illustrated in the drawings, unless otherwise noted. The dimensional ratio of each element is not limited to the ratio illustrated in the drawings.

Only one type of materials exemplified herein can be used, or two or more types thereof can be used together, unless otherwise noted. In a case where there are a plurality of substances corresponding to each component in a composition, the content of each component in the composition indicates the total amount of the plurality of substances in the composition, unless otherwise noted.

One embodiment of a nitride fluorescent material is a nitride fluorescent material represented by General Formula: MAlSiN₃ (M=Ca, Sr) in which a part of M is substituted with Eu and a main crystal phase has the same structure as that of a CaAlSiN₃ crystal phase. The nitride fluorescent material may have different phases within a range not departing from the gist of the present disclosure. In the nitride fluorescent material, the ratio of the main crystal phase may be generally 80 mass % or more, 90 mass % or more, 95 mass % or more, or 98 mass % or more, with respect to the total amount of the nitride fluorescent material.

The nitride fluorescent material is a nitride fluorescent material that has the same crystalline structure as that of CaAlSiN₃ and contains Eu and Sr as a constituent element, in which a light emission peak wavelength is 640 nm or more, and a half width of the light emission peak wavelength is 80 nm or less. The nitride fluorescent material that has the same crystalline structure as that of CaAlSiN₃ and contains Eu and Sr as the constituent element is also referred to as a SCASN fluorescent material. In the nitride fluorescent material, light emission intensity is excellent and a decrease in the light emission intensity is sufficiently suppressed even at a high temperature (for example, 200° C.), and thus, the nitride fluorescent material is useful as a red fluorescent material that is used for illuminations. When the nitride fluorescent material is used for illuminations, the nitride fluorescent material may be used as a fluorescent material composition (also referred to as a fluorescent material package) in combination with other fluorescent materials.

The light emission peak wavelength of the nitride fluorescent material, for example, may be 642 nm or more or 644 nm or more. By setting the lower limit value of the light emission peak wavelength to be in the range described above, deeper red light may be emitted, and in a case where the nitride fluorescent material is used as a red fluorescent material for a white LED, higher color rendering properties may be exhibited. In addition, by setting the lower limit value of the light emission peak wavelength to be in the range described above, a color reproduction range of a light emission device using the nitride fluorescent material may be further expanded. The light emission peak wavelength of the nitride fluorescent material, for example, may be 655 nm or less or 650 nm or less. By setting the upper limit value of the light emission peak wavelength to be in the range described above, an increase in the value of the half width may be suppressed, and the light emission intensity may be more excellent. The light emission peak wavelength of the nitride fluorescent material, for example, may be adjusted by increasing the content of the element that is a light emission center (for example, Eu or the like) in the nitride fluorescent material.

The half width of the light emission peak wavelength of the nitride fluorescent material, for example, may be 78 nm or less or 76 nm or less. By setting the upper limit value of the half width of the light emission peak wavelength to be in the range described above, the light emission intensity of the nitride fluorescent material and the suppression of a decrease in the light emission intensity at a higher temperature are compatible with each other at a high level. The half width of the light emission peak wavelength of the nitride fluorescent material is generally 50 nm or more, and may be 60 nm or more or 65 nm or more. By setting the lower limit value of the half width of the light emission peak wavelength to be in the range described above, the nitride fluorescent material excellent in the light emission intensity may be obtained. The half width of the light emission peak wavelength of the nitride fluorescent material, for example, may be adjusted by a ratio of the content of Sr and the content of Eu, or the like.

Herein, the light emission peak wavelength of the fluorescent material indicates a value that is determined by fluorescence spectrum measurement with respect to an excitation wavelength of 455 nm. The fluorescence spectrum measurement of the light emission peak wavelength of the fluorescent material is performed at 25° C. Herein, the “half width” indicates a full width at half maximum (FWHM), and can be determined from a fluorescence spectrum to be obtained by the fluorescence spectrum measurement with respect to the excitation wavelength of 455 nm.

The nitride fluorescent material is excellent in the light emission intensity at 25° C., and is sufficiently excellent in the light emission intensity even at a high temperature (for example, 200° C.). A maintenance rate of the light emission intensity of the nitride fluorescent material at 200° C. to the light emission intensity at 25° C., for example, may be 70% or more, and may also be 72% or more or 74% or more. By setting the maintenance rate of the light emission intensity of the nitride fluorescent material to be in the range described above, the nitride fluorescent material may be used in the purpose in which the environmental temperature increases while in use, which is useful as a red fluorescent material for illuminations. The maintenance rate of the light emission intensity of the nitride fluorescent material, for example, may be improved by adjusting the ratio of the content of Sr and the content of Eu in the nitride fluorescent material.

The nitride fluorescent material may contain halogen as the constituent element. In a case where the nitride fluorescent material contains halogen, the nitride fluorescent material has the light emission peak wavelength in a longer wavelength range, which is more useful as the red fluorescent material. The content of halogen in the nitride fluorescent material, for example, may be 200 μg/g or more, 300 μg/g or more, or 500 μg/g or more, on the basis of the total amount of the nitride fluorescent material. By setting the lower limit value of the content of halogen in the nitride fluorescent material to be in the range described above, a decrease in the light emission intensity of the nitride fluorescent material may be suppressed. The present inventors have assumed that such an effect is obtained because the crystalline structure of the nitride fluorescent material is maintained in a state in which a high quantum efficiency may be exhibited. The content of halogen in the nitride fluorescent material, for example, may be 2000 μg/g or less, 1500 μg/g or less, or 1000 μg/g or less. Examples of halogen described above, for example, are capable of including fluorine (F), chlorine (Cl), bromine (Br), iodine (I), and the like. The nitride fluorescent material preferably contains fluorine.

The nitride fluorescent material, for example, may be manufactured by a manufacturing method as described below. One embodiment of the manufacturing method of the nitride fluorescent material represented by General Formula: MAlSiN₃ (M=Ca, Sr) in which a part of M is substituted with Eu and the main crystal phase has the same structure as that of the CaAlSiN₃ crystal phase includes a first step of heating a raw material powder containing a nitride and a europium halide to obtain a first fluorescent material, and a second step of heating the first fluorescent material at a temperature lower than that in the first step to obtain a second fluorescent material (the nitride fluorescent material). In the manufacturing method of the nitride fluorescent material, the europium halide is used as the raw material powder. In the manufacturing method of the nitride fluorescent material, the occurrence of a defect in a crystalline lattice of the fluorescent material to be obtained may be suppressed, compared to a manufacturing method of a nitride fluorescent material of the related art in which europium is blended as an oxide or a nitride, and thus, the content of Eu in the nitride fluorescent material to be obtained may be more easily increased.

The first step is a step of forming the first fluorescent material having the same crystalline structure as that of CaAlSiN₃ by heating the raw material powder containing the nitride and the europium halide. A heating temperature in the first step, for example, may be higher than 1650° C., or may be 1700° C. or higher. By setting the lower limit value of the heating temperature to be in the range described above, a reaction for forming the first fluorescent material may be more sufficiently processed, and the amount of unreacted substance may be further reduced. The heating temperature in the first step, for example, may be 2000° C. or lower. By setting the upper limit value of the heating temperature to be in the range described above, the occurrence of a defect due to partial decomposition of the main crystal phase having the same crystalline structure as that of CaAlSiN₃ may be suppressed. The heating temperature may be adjusted in the range described above, and for example, may be 1700 to 2000° C.

The first step, for example, may be performed in an inert gas atmosphere. The inert gas, for example, may contain nitrogen, argon, and the like, preferably, the inert gas may contain nitrogen, and more preferably, the inert gas may be nitrogen. The first step may be performed in an atmosphere in which the pressure is adjusted. A pressure (a gauge pressure) in the first step, for example, may be less than 1 MPaG, or may be 0.9 MPaG or less. By setting the upper limit value of the pressure to be in the range described above, productivity may be further improved. The pressure (the gauge pressure) in the first step, for example, may be 0.1 MPaG (the atmospheric pressure) or more, 0.5 MPaG or more, 0.7 MPaG or more, or 0.8 MPaG or more. By setting the lower limit value of the pressure to be in the range described above, the pyrolysis of the first fluorescent material to be formed in the process of the heating treatment of the raw material powder may be more sufficiently suppressed.

A heating time of the raw material powder in the first step, for example, may be 2 to 24 hours or 5 to 15 hours. By adjusting the heating time, the amount of unreacted substance in the raw material powder may be further reduced, and crystalline growth may be controlled.

The nitride used in the first step may include nitrides of the elements configuring the nitride fluorescent material described above. Examples of the nitride include strontium nitride (Sr₃N₂), calcium nitride (Ca₃N₂), europium nitride (EuN), aluminum nitride (AlN), silicon nitride (Si₃N₄), and the like.

Examples of the europium halide used in the first step include europium fluoride, europium chloride, europium bromide, europium iodide, and the like. By using the europium halide, the occurrence of a defect in the crystalline lattice that is caused by the incorporation of oxygen atoms derived from the raw material powder in the crystalline structure may be suppressed, and light emission properties and temperature properties of the nitride fluorescent material to be obtained may be improved, compared to the case of using a europium oxide. The valence of europium in the europium halide may be a valence of two, and may be a valence of three. Examples of the europium fluoride include EuF₂ and EuF₃. Examples of the europium chloride include EuCl₂ and EuCl₃. Examples of the europium bromide include EuBr₂ or EuBr₃. Examples of the europium iodide include EuI₂ or EuI₃. Preferably, the europium halide contains europium fluoride, and more preferably, the europium halide is europium fluoride. Preferably, the europium fluoride is EuF₃. By using the fluoride excellent in handleability, industrial productivity may be improved, compared to the case of using other halides. In addition, by using the fluoride as the europium halide, a reaction according to the heating of the raw material powder is smoothly processed, and the formation of different phases tends to be further suppressed.

The raw material powder may contain other compounds in addition to the nitride and the europium halide. Examples of the other compounds may include oxides, hydrides, carbonates, and the like of the elements configuring the nitride fluorescent material described above.

The manufacturing method of the nitride fluorescent material may include a step of adjusting the content of Sr in the raw material powder, and may include a step of adjusting the content of Eu with respect to the content of Sr in the raw material powder, before the first step.

The second step is a step of obtaining the second fluorescent material (the nitride fluorescent material) by heating the first fluorescent material obtained as described above at a temperature lower than that in the first step. According to the second step, a crystalline defect or the like in the first fluorescent material may be reduced, and the light emission peak wavelength and the half width of the peak wavelength may be adjusted through the step.

A heating temperature in the second step, for example, may be 1100° C. or higher or 1200° C. or higher. By setting the lower limit value of the heating temperature to be in the range described above, the crystalline defect or the like in the first fluorescent material may be more sufficiently reduced. The heating temperature in the second step, for example, may be 1650° C. or lower or 1450° C. or lower. By setting the upper limit value of the heating temperature to be in the range described above, the partial decomposition of the main crystal phase having the same crystalline structure as that of CaAlSiN₃ in the first fluorescent material may be sufficiently suppressed. The heating temperature may be adjusted in the range described above, and for example, may be 1100 to 1650° C.

The second step, for example, may be performed in an inert gas atmosphere identical to that in the first step, or may be performed in an inert gas atmosphere different from that in the first step. As the inert gas, the gas exemplified in the first step may be used, preferably, the inert gas contains argon, and more preferably, the inert gas is argon. The second step may be performed in a pressure atmosphere identical to that in the first step, or may be performed in a pressure atmosphere different from that in the first step. A pressure (a gauge pressure) in the second step, for example, may be 0.65 MPaG or less, 0.1 MPaG or less, or 0.01 MPaG or less. By setting the upper limit value of the pressure to be in the range described above, the crystalline defect in the first fluorescent material may be more sufficiently reduced, and the light emission intensity of the nitride fluorescent material may be further improved. The pressure (the gauge pressure) in the second step is not particularly limited, and may be 0.001 MPaG or more or 0.002 MPaG or more, in consideration of the industrial productivity.

A heating time of the first fluorescent material in the second step, for example, may be 4 to 24 hours or 8 to 15 hours. By adjusting the heating time, the crystalline defect of the first fluorescent material may be reduced, and the light emission intensity of the nitride fluorescent material may be further improved.

It is preferable to use a container containing a material that is stable at a high temperature and in an inert atmosphere at a high temperature, and is less likely to react with the raw material powder, the first fluorescent material, the second fluorescent material (the nitride fluorescent material), and the like, as a container used in the manufacturing method of the nitride fluorescent material. Such a container is preferably a metal container containing molybdenum, tantalum, tungsten, and an alloy containing such metals, and is more preferably a container with a lid.

The manufacturing method of the nitride fluorescent material may include other steps in addition to the first step, the second step, and the step of adjusting the composition in the raw material powder. Examples of the other steps include a step of performing an acidic treatment with respect to the second fluorescent material (the nitride fluorescent material) obtained in the second step, and the like. According to the acidic treatment of the nitride fluorescent material, the content of impurities in the fluorescent material may be reduced. Examples of an acid are capable of including a hydrochloric acid, a formic acid, an acetic acid, a sulfuric acid, a nitric acid, and the like. After the acidic treatment, the nitride fluorescent material may be washed with water to remove the acid and dried.

The nitride fluorescent material to be obtained by the manufacturing method described above may be obtained as fine particles. A median size (d50) of the nitride fluorescent material, for example, may be 1 to 50 μm. By setting the median size to be in the range described above, excitation light may be received, a decrease in the light emission intensity may be sufficiently suppressed, and a variation in the chromaticity of fluorescence emitted from the nitride fluorescent material may be suppressed. Herein, the “median size (d50)” indicates a value to be calculated from a volume average diameter that is measured by a laser diffraction scattering method, on the basis of the description in JIS R 1622:1997.

The nitride fluorescent material to be obtained by the manufacturing method described above, for example, has a composition as described below. In the nitride fluorescent material, the content of Eu may be 4.5 to 7.0 mass %, the content of Sr may be 30 to 42 mass %, and the content of Ca may be 0.8 to 3.0 mass %. By setting the content of Eu, the content of Sr, and the content of Ca in the nitride fluorescent material to be in the range described above, the light emission intensity of the nitride fluorescent material and the suppression of a decrease in the light emission intensity at a high temperature are compatible with each other at a higher level.

The content of Eu in the nitride fluorescent material, for example, may be 5.0 to 7.0 mass % or 5.0 to 6.0 mass %. The content of Sr in the nitride fluorescent material, for example, may be 34.0 to 41.0 mass % or 36.0 to 40.0 mass %. The content of Ca in the nitride fluorescent material, for example, may be 0.8 to 2.9 mass %, 0.8 to 2.8 mass %, 0.8 to 1.0 mass %, or 0.8 to 0.9 mass %. By setting the content of Eu, the content of Sr, and the content of Ca to be in the range described above, the nitride fluorescent material may be obtained in which the crystalline defect is further reduced.

The nitride fluorescent material described above may be represented by General Formula: MAlSiN₃ (M=Ca, Sr, Eu), and the main crystal phase has the same structure as that of the CaAlSiN3 crystal phase. The content of Eu that is a light emission center element in the nitride fluorescent material (the SCASN fluorescent material) is adjusted in combination with the content of Ca and the content of Sr that are capable of occupying the same site on the crystalline lattice. For example, in the case of increasing the content of Eu, the total amount of the content of Ca and the content of Sr relatively decreases. In the manufacturing method of the nitride fluorescent material of the related art, in the case of increasing a blending amount of a compound having a light emission center (for example, a europium compound or the like) in the raw material powder, a side reaction such as the light emission center being incorporated in different phases such as Sr₂Si₅N₈ but not in the fluorescent material or in the main crystal phase is processed, and it is difficult to increase the content of the element that is the light emission center (for example, Eu or the like) in the fluorescent material.

In addition, in the manufacturing method of the nitride fluorescent material of the related art, in the case of using a compound containing oxygen as a supply source of each of the elements, any of the elements in the crystalline lattice described above is substituted with an oxygen atom by oxygen derived from the compound, and a defect occurs in the crystalline lattice. According to the studies of the present inventors, in the case of using oxide as the compound for supplying the element that is the light emission center, in particular, the occurrence of a defect in the crystalline lattice tends to increase. As a result thereof, the light emission peak wavelength of the nitride fluorescent material to be obtained does not become a long wavelength as expected or the half width of the light emission peak wavelength is widened, and thus, the light emission intensity is not exhibited as expected. The manufacturing method of the nitride fluorescent material according to the present disclosure has been made on the basis of such findings, and in the manufacturing method, the nitride fluorescent material may be prepared in which the light emission peak wavelength is 640 nm or more, and the half width of the light emission peak wavelength is 80 nm or less, by decreasing the amount of oxide in the raw material powder at the time of preparing the nitride fluorescent material, in particular, by adjusting the amount of oxide using the halide as the compound for supplying the light emission center element. Further, since a defect in the crystalline lattice is reduced, the nitride fluorescent material is also excellent in the temperature properties.

The nitride fluorescent material described above may be used alone, may be used in combination with other fluorescent materials, or may be used as the fluorescent material composition. One embodiment of the fluorescent material composition contains the nitride fluorescent material described above, and other fluorescent materials.

Examples of the other fluorescent materials include a red fluorescent material, a yellow fluorescent material, a yellow-green fluorescent material, a green fluorescent material, and the like. The other fluorescent materials may be selected in accordance with the purpose of using the fluorescent material composition, and for example, may be combined by being selected in accordance with luminance, shade, color rendering properties, or the like to be required for the light emission device. Examples of the red fluorescent material include a nitride fluorescent material (a CASN fluorescent material) containing CaSiAlN₃, a SCASN fluorescent material having a light emission peak wavelength of less than 640 nm, and the like. Examples of green to yellow fluorescent materials (fluorescent materials having a fluorescence wavelength in green to yellow wavelength bands) include a LuAG fluorescent material, a YAG fluorescent material, and the like, examples of the yellow fluorescent material include a Ca-α-SiAlON fluorescent material and the like, and examples of the green fluorescent material include a β-SiAlON fluorescent material and the like.

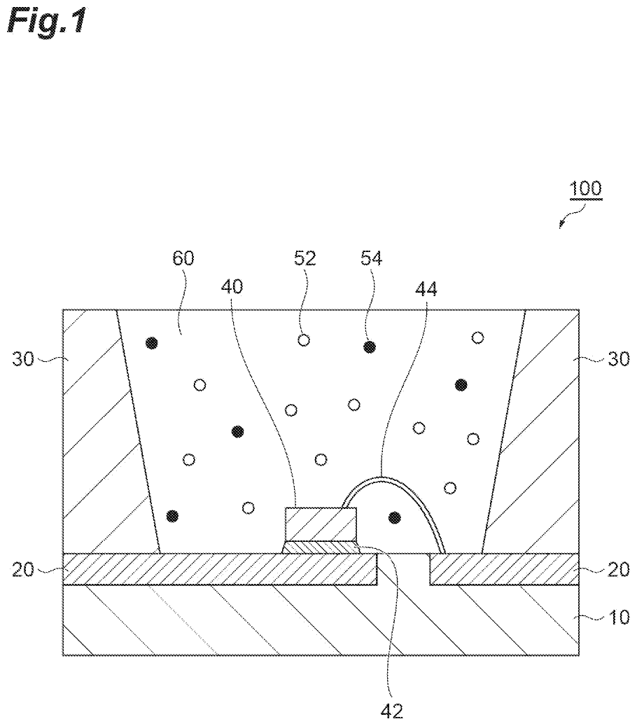

The nitride fluorescent material described above, for example, may be used in a light emission device such as a white LED. One embodiment of the light emission device includes the nitride fluorescent material, and a light emission element. FIG. 1 is a schematic sectional view illustrating an example of the light emission device. The light emission device illustrated in FIG. 1 is an example of an optical semiconductor device that is sorted as a surface-mounted device. A light emission device 100 includes a base material 10, a metal layer 20 provided on the surface of the base material 10, a light emission element 40 electrically connected to the metal layer 20, a reflective portion 30 provided on the base material 10 to surround the light emission element 40, and a transparent sealing resin 60 filling a concave portion formed by the base material 10 and the reflective portion 30 to seal the light emission element 40. In the transparent sealing resin 60, nitride fluorescent materials 52 and other fluorescent materials 54 are dispersed.

The metal layer 20 is formed on a part of the surface of the base material 10, and the metal layer 20 is an electrode that is electrically conductive with the light emission element 40 disposed on the surface of the base material 10. The light emission element 40 is die-bonded to the metal layer 20 on either an anode side or a cathode side and electrically connected to the metal layer 20 via a die bonding material 42. The light emission element 40 is electrically connected to the metal layer 20 on either the anode side or the cathode side via a bonding wire 44.

The reflective portion 30 is filled with the transparent sealing resin 60 for sealing the light emission element 40 and reflects light emitted from the light emission element 40 (excitation light), and fluorescence emitted from the nitride fluorescent material 52 and the other fluorescent material 54 by receiving the light described above on the surface side of the light emission device 100. The nitride fluorescent material 52 and the other fluorescent material 54 are exposed to a situation at a high temperature by the excitation light from the light emission element 40, and the fluorescence, as described above. In the light emission device 100, the nitride fluorescent material described above is used as the nitride fluorescent material 52. By using the nitride fluorescent material described above, even in a case where the temperature increases with use, a decrease in the light emission intensity is suppressed. In addition, a decrease in the luminance is suppressed even at a high temperature due to long-term use of the light emission device 100. That is, in the light emission device 100, a decrease in the luminance due to the use in a high temperature environment is also suppressed.

The light emission element 40 may emit light that is capable of exciting the nitride fluorescent material 52 and the other fluorescent material 54. The light emission element 40, for example, may be a near-ultraviolet light emission diode (a near-ultraviolet LED), an ultraviolet light emission diode (an ultraviolet LED), a blue light emission diode (a blue LED), and the like.

The fluorescent material of the light emission device 100 includes the other fluorescent material 54 in addition to the nitride fluorescent material 52, but may be only the nitride fluorescent material 52. Examples of the other fluorescent material 54 may include a red fluorescent material, a yellow fluorescent material, a green fluorescent material, a blue fluorescent material, and the like.

In the example described above, the light emission device has been described with the example of the optical semiconductor device that is sorted as the surface-mounted device, but is not limited thereto. The light emission device, for example, may be an illumination device, a signal device, an image display device, a light emission panel, a liquid crystal display, and a backlight of a liquid crystal panel or the like.

Some embodiments have been described above, but the present disclosure is not limited to the embodiments described above.

### EXAMPLES

The contents of the present disclosure will be described in more detail with reference to Examples and Comparative Examples, but the present disclosure is not limited to Examples described below.

### Example 1

<Preparation of Nitride Fluorescent Material>

63.4 g of α-type silicon nitride (Si₃N₄, manufactured by Ube Industries, Ltd., SN-E10 grade), 55.6 g of aluminum nitride (AlN, manufactured by Tokuyama Corporation, E grade), and 16.7 g of europium fluoride (EuF₃, manufactured by FUJIFILM Wako Pure Chemical Corporation) were weighed and preliminarily mixed in a container. Next, in a glove box retained in a nitrogen atmosphere in which the moisture was adjusted to 1 mass ppm or less and the concentration of oxygen was adjusted to 50 ppm or less, 5.4 g of calcium nitride (Ca₃N₂, manufactured by Materion Corporation) and 109.1 g of strontium nitride (Sr₃N₂, purity of 2 N, manufactured by Kojundo Chemical Laboratory Co., Ltd.) were further weighed and dry-mixed in the container described above to obtain a raw material powder (a mix powder).

In the glove box, a tungsten container with a lid was filled with 250 g of the raw material powder described above. The container with a lid was taken out from the glove box, disposed in an electric furnace provided with a carbon heater, and then, sufficiently vacuum-exhausted until the pressure in the electric furnace was 0.1 PaG or less. While the vacuum exhaustion was continuously performed, the temperature in the electric furnace was increased to 600° C. After the temperature reached 600° C., nitrogen gas was introduced into the electric furnace such that the pressure in the electric furnace was adjusted to 0.9 MPaG. After that, in a nitrogen gas atmosphere, the temperature in the electric furnace was increased to 1950° C., and a heating treatment (corresponding to the first step) was performed for 8 hours after the temperature reached 1950° C. After that, the heating was ended, and cooling was performed to a room temperature. After the cooling was performed to a room temperature, a red lump was collected from the container. The collected lump was crushed with a mortar, and finally, a powder (a burned powder) that had passed through a sieve having a mesh size of 75 μn was obtained.

The tungsten container was filled with the obtained burned powder, promptly moved into the electric furnace provided with a carbon heater, and sufficiently vacuum-exhausted until the pressure in the furnace was 0.1 PaG or less. While the vacuum exhaustion was continuously performed, heating was started, and when the temperature reached 600° C., argon gas was introduced into the furnace such that the pressure in the furnace atmosphere was adjusted to 0.2 MPaG. The temperature was continuously increased to 1300° C. even after the introduction of the argon gas was started. A heating treatment (an annealing treatment, corresponding to the second step) was performed for 8 hours after the temperature reached 1300° C. After that, the heating was ended, and cooling was performed to a room temperature. After the cooling was performed to a room temperature, the powder after the annealing treatment was collected from the container. The collected powder passed through the sieve having a mesh size of 75 μm such that a particle size was adjusted, and a red fluorescent material was obtained.

After the heating treatment, the heating in the electric furnace was stopped, and cooling was performed to a room temperature. A sample that was lumpy in the container with a lid was collected in a mortar and crushed. After the crushing, the sample passed through the sieve having a mesh size of 75 μm to obtain a red fluorescent material of Example 1 (a nitride fluorescent material, Median Size (d50): 25 μm).

### Example 2

63.1 g of α-type silicon nitride (Si₃N₄, manufactured by Ube Industries, Ltd., SN-E10 grade), 55.2 g of aluminum nitride (AlN, manufactured by Tokuyama Corporation, E grade), and 16.9 g of europium fluoride (EuF₃, manufactured by FUJIFILM Wako Pure Chemical Corporation) were weighed and preliminarily mixed in a container. Next, in a glove box retained in a nitrogen atmosphere in which the moisture was adjusted to 1 mass ppm or less and the concentration of oxygen was adjusted to 50 ppm or less, 6.0 g of calcium nitride (Ca₃N₂, manufactured by Materion Corporation) and 108.6 g of strontium nitride (Sr₃N₂, purity of 2 N, manufactured by Kojundo Chemical Laboratory Co., Ltd.) were further weighed and dry-mixed in the container described above to obtain a raw material powder. The subsequent steps were performed as with Example 1 to obtain a red fluorescent material of Example 2 (a nitride fluorescent material, Median Size (d50): 25 μm).

### Comparative Example 1

64.4 g of an α-type silicon nitride powder (Si₃N₄, manufactured by Ube Industries, Ltd., SN-E10 grade), 56.4 g of an aluminum nitride powder (AlN, manufactured by Tokuyama Corporation, E grade), and 2.9 g of europium oxide (Eu₂O₃, manufactured by Shin-Etsu Chemical Co., Ltd., RU grade) were weighed and preliminarily mixed in a container. Next, in a glove box retained in a nitrogen atmosphere in which the moisture was adjusted to 1 mass ppm or less and the concentration of oxygen was adjusted to 50 ppm or less, 2.6 g of calcium nitride (Ca₃N₂, manufactured by Materion Corporation) and 123.7 g of strontium nitride (Sr₃N₂, purity of 2 N, manufactured by Kojundo Chemical Laboratory Co., Ltd.) were further weighed and dry-mixed in the container described above to obtain a raw material powder. The subsequent steps were performed as with Example 1 to obtain a red fluorescent material of Comparative Example 1 (a nitride fluorescent material, Median Size (d50): 25 μm).

### Comparative Example 2

66.8 g of an α-type silicon nitride powder (Si₃N₄, manufactured by Ube Industries, Ltd., SN-E10 grade), 58.6 g of an aluminum nitride powder (AlN, manufactured by Tokuyama Corporation, E grade), and 7.6 g of europium oxide (Eu₂O₃, manufactured by Shin-Etsu Chemical Co., Ltd., RU grade) were weighed and preliminarily mixed in a container. Next, in a glove box retained in a nitrogen atmosphere in which the moisture was adjusted to 1 mass ppm or less and the concentration of oxygen was adjusted to 50 ppm or less, 15.5 g of calcium nitride (Ca₃N₂, manufactured by Materion Corporation) and 101.5 g of strontium nitride (Sr₃N₂, purity of 2 N, manufactured by Kojundo Chemical Laboratory Co., Ltd.) were further weighed and dry-mixed in the container described above to obtain a raw material powder. The subsequent steps were performed as with Example 1 to obtain a red fluorescent material of Comparative Example 2 (a nitride fluorescent material, Median Size (d50): 21 μm).

### Comparative Example 3

66.5 g of an α-type silicon nitride powder (Si₃N₄, manufactured by Ube Industries, Ltd., SN-E10 grade), 58.3 g of an aluminum nitride powder (AlN, manufactured by Tokuyama Corporation, E grade), and 5.0 g of europium oxide (Eu₂O₃, manufactured by Shin-Etsu Chemical Co., Ltd., RU grade) were weighed and preliminarily mixed in a container. Next, in a glove box retained in a nitrogen atmosphere in which the moisture was adjusted to 1 mass ppm or less and the concentration of oxygen was adjusted to 50 ppm or less, 12.6 g of calcium nitride (Ca₃N₂, manufactured by Materion Corporation) and 107.6 g of strontium nitride (Sr₃N₂, purity of 2 N, manufactured by Kojundo Chemical Laboratory Co., Ltd.) were further weighed and dry-mixed in the container described above to obtain a raw material powder. The subsequent steps were performed as with Example 1 to obtain a red fluorescent material of Comparative Example 3 (a nitride fluorescent material, Median Size (d50): 37 μm).

### Comparative Example 4

63.8 g of an α-type silicon nitride powder (Si₃N₄, manufactured by Ube Industries, Ltd., SN-E10 grade), 55.9 g of an aluminum nitride powder (AlN, manufactured by Tokuyama Corporation, E grade), and 14.4 g of europium oxide (Eu₂O₃, manufactured by Shin-Etsu Chemical Co., Ltd., RU grade) were weighed and preliminarily mixed in a container. Next, in a glove box retained in a nitrogen atmosphere in which the moisture was adjusted to 1 mass ppm or less and the concentration of oxygen was adjusted to 50 ppm or less, 6.0 g of calcium nitride (Ca₃N₂, manufactured by Materion Corporation) and 109.7 g of strontium nitride (Sr₃N₂, purity of 2 N, manufactured by Kojundo Chemical Laboratory Co., Ltd.) were further weighed and dry-mixed in the container described above to obtain a raw material powder. The subsequent steps were performed as with Example 1 to obtain a red fluorescent material of Comparative Example 4 (a nitride fluorescent material, Median Size (d50): 24 μm).

<Check of Crystalline Structure of Red Fluorescent Material>

For the red fluorescent materials obtained in Examples 1 and 2 and Comparative Examples 1 to 4, an X-ray diffraction pattern with respect to each of the red fluorescent materials was acquired by a powder X-ray analysis method using an X-ray diffraction device (manufactured by Rigaku Corporation, Product Name: UltimaIV). A crystalline structure was checked from the obtained X-ray diffraction pattern. As a result thereof, the same diffraction pattern as that of CaAlSiN₃ crystals was checked in all of the X-ray diffraction patterns of the red fluorescent materials of Examples 1 and 2 and Comparative Examples 1 to 4. Note that, in the measurement, CuKα rays (character X-rays) were used.

<Composition Analysis of Red Fluorescent Material>

For the red fluorescent materials obtained in Examples 1 and 2 and Comparative Examples 1 to 4, composition analysis was performed. First, the red fluorescent material was dissolved by a pressurized acidolysis method to prepare a sample solution. Quantitative analysis of elements was performed with an ICP emission spectrophotometer (manufactured by Rigaku Corporation, Product Name: CIROS-120) by using the obtained sample solution as a target. Results are shown in Table 1.

From the results of the crystalline structure and the composition analysis described above, it was checked that all of the red fluorescent materials obtained in Examples 1 and 2 and Comparative Examples 1 to 4 were SCASN fluorescent materials.

<Evaluation of Content of Fluorine in Nitride Fluorescent Material>

For the SCASN fluorescent materials obtained in Examples 1 and 2 and Comparative Examples 1 to 4, the content of fluorine was evaluated. The SCASN fluorescent material was burned by using an automatic sample burner (manufactured by Nittoseiko Analytech Co., Ltd., Product Name: AQF-2100H) to prepare a sample solution in which the generated gas was absorbed. The content of fluorine was measured with respect to the prepared sample solution by an ion chromatography method. Results are shown in Table 1. Note that, in Table 1, a case where the content of fluorine in the nitride fluorescent material was a detection limit or less was represented as “-”.

A measurement condition of the ion chromatography method described above is as follows.

Device: ion chromatograph (manufactured by Thermo Fisher Scientific K.K., Product Name: ICS-2100)

Column: AS17-C (manufactured by Thermo Fisher Scientific K.K., Product Name)

Introduction Amount: 25 μL

Eluent: potassium hydroxide (KOH) solution

Liquid Sending Speed: 1.00 mL/minute

Measurement Temperature: 35° C.

TABLE 1

| | Composition analysis | | | Content of |
|---|---|---|---|---|
| | [mass %] | | | fluorine |
| | Eu | Sr | Ca | [μg/g] |
| Example 1 | 4.5 | 36.0 | 2.4 | 350 |
| Example 2 | 4.8 | 31.5 | 1.9 | 1530 |
| Comparative Example 1 | 1.0 | 42.6 | 1.2 | — |
| Comparative Example 2 | 1.7 | 36.4 | 4.2 | — |
| Comparative Example 3 | 2.9 | 35.9 | 3.7 | — |
| Comparative Example 4 | 5.1 | 40.0 | 2.2 | — |

<Measurement of Light Emission Peak Wavelength and Half Width of Nitride Fluorescent Material>

For the SCASN fluorescent materials obtained in Examples 1 and 2 and Comparative Examples 1 to 4, a light emission peak wavelength and a half width were measured. A fluorescence spectrum was measured by using a fluorospectrophotometer (manufactured by Hitachi High-Tech Corporation, Product Name: F-7000) corrected by rhodamine B and a sub-standard light source. In the measurement, the fluorescence spectrum with respect to an excitation wavelength of 455 nm was measured by using a solid sample holder attached to the photometer. From the obtained fluorescence spectrum, the light emission peak wavelength and the half width of the light emission peak wavelength were determined. Results are shown in Table 2.

<Measurement of Light Emission Intensity and Light Emission Intensity Maintenance Rate at 200° C. of Nitride Fluorescent Material>

For the SCASN fluorescent materials obtained in Examples 1 and 2 and Comparative Examples 1 to 4, light emission intensity and a light emission intensity maintenance rate at 200° C. were measured. Specifically, the measurement was performed by the following method.

A concave cell was filled with the SCASN fluorescent material prepared as described above such that a smooth sample surface was formed. The cell filled with the SCASN fluorescent material was set in a lateral opening portion (ϕ10 mm) of an integrating sphere (ϕ60 mm) Monochromatic light dispersed to a wavelength of 455 nm was introduced to the integrating sphere from a light emission light source (a Xe lamp) by an optical fiber, and an excitation reflection spectrum and a fluorescence spectrum were measured by using a spectrophotometer (manufactured by Otsuka Electronics Co., Ltd., Product Name: QE-2100). The light emission intensity at 25° C. was obtained from the obtained fluorescence spectrum.

Further, the inside of the cell filled with the SCASN fluorescent material described above was heated, and the fluorescence spectrum of the SCASN fluorescent material at 200° C. was measured by the same method as described above to obtain the light emission intensity at 200° C. From the obtained light emission intensity, the light emission intensity maintenance rate at 200° C. was calculated on the basis of Expression (1) described below. Results are shown in Table 2. Note that, the light emission intensity shown in Table 2 is a relative value based on the light emission intensity of the SCASN fluorescent material prepared in Comparative Example 4, which is measured at 25° C.

Light Emission Intensity Maintenance Rate [%]=[(Light Emission Intensity at 200° C.)/(Light Emission Intensity at 25° C.)]×100 Expression (1)

TABLE 2

| | | | | Light |
|---|---|---|---|---|
| | Light | | | emission |
| | emission | | Light | intensity |
| | peak | Half | emission | maintenance |
| | wavelength | width | intensity | rate at 200° C. |
| | [nm] | [nm] | [%] | [%] |
| Example 1 | 642 | 76 | 100 | 75 |
| Example 2 | 644 | 78 | 99 | 73 |
| Comparative | 620 | 73 | 114 | 82 |
| Example 1 | | | | |
| Comparative | 636 | 85 | 93 | 82 |
| Example 2 | | | | |
| Comparative | 651 | 93 | 86 | 81 |
| Example 3 | | | | |
| Comparative | 639 | 77 | 100 | 69 |
| Example 4 | | | | |

### INDUSTRIAL APPLICABILITY

According to the present disclosure, it is possible to provide a nitride fluorescent material in which light emission intensity is excellent and a decrease in the light emission intensity is suppressed even at a high temperature. By using the nitride fluorescent material that is capable of emitting red fluorescence, as described above, it is possible to provide a light emission device in which a decrease in luminance is suppressed even at a high temperature.

### REFERENCE SIGNS LIST

10: base material, 20: metal layer, 30: reflective portion, 40: light emission element, 42: die bonding material, 44: bonding wire, 52: nitride fluorescent material, 54: other fluorescent material, 60: transparent sealing resin, 100: light emission device.

1. A nitride fluorescent material represented by General Formula: MAlSiN₃ (M=Ca, Sr) in which a part of M is substituted with Eu and a main crystal phase has the same structure as that of a CaAlSiN₃ crystal phase,
wherein a light emission peak wavelength is 640 nm or more, and a half width of the light emission peak wavelength is 80 nm or less.

2. The nitride fluorescent material according to claim 1,
wherein the nitride fluorescent material further contains halogen as a constituent element.

3. The nitride fluorescent material according to claim 2,
wherein a content of halogen is 200 μg/g or more.

4. A light emission device, comprising:
the nitride fluorescent material according to claim 1; and
a light emission element.

5. The nitride fluorescent material according to claim 2,
wherein the halogen comprises at least one selected from the group of fluorine, chlorine, bromine, and iodine.
